(19) United States
(12) Patent Application Publication
(10) Pub. No.: US 2025/0393378 A1
(43) Pub. Date: Dec. 25, 2025

(54) OPTICAL SUBSTRATE, DISPLAY DEVICE AND PREPARATION METHOD OF DISPLAY DEVICE

(71) Applicant: Lextar Electronics Corporation, Hsinchu City (TW)

(72) Inventors: Soh Deng KONG, Hsinchu City (TW); Fu-Hsin CHEN, Hsinchu City (TW); Wen-Wan TAI, Hsinchu City (TW); Yu-Chun LEE, Hsinchu City (TW)

(21) Appl. No.: 19/240,813

(22) Filed: Jun. 17, 2025

(30) Foreign Application Priority Data
Jun. 19, 2024 (TW) 113122634

(51) Int. Cl. H10H 29/855; G02B 5/00; G02B 5/08; H10H 29/01; H10H 29/856

(52) U.S. Cl. CPC H10H 29/8552; G02B 5/003; G02B 5/0808; H10H 29/012; H10H 29/0363; H10H 29/856

(57) ABSTRACT

An optical substrate includes a transparent matrix substrate, a reflective film, and a light-absorbing film. The transparent matrix substrate includes a first surface, a second surface, and openings. The openings are in the transparent matrix substrate. The openings include an opening sidewall connecting the first surface and the second surface. Each of the opening sidewalls includes a first portion and a second portion. The reflective film extends from the first surface and is attached to the first portion of each opening sidewall. The light-absorbing film is attached only to the second surface or attached to the second surface and further extending to the second portion of the opening sidewall.

### CROSS REFERENCE TO RELATED APPLICATIONS

This Application claims priority of Taiwan Patent Application No. 113122634, filed on Jun. 19, 2024, the entirety of which is incorporated by reference herein.

### BACKGROUND

### Field of the Disclosure

The present disclosure relates to an optical substrate, a display device including the optical substrate, and a method for preparing the display device, and, in particular, it relates to an optical substrate including a reflective film and a light-absorbing film, a display device including the optical substrate, and a method for preparing the display device.

### Description of the Related Art

A typical display device includes a black matrix, which is used to reduce color interference between pixels and increase the contrast of the display device. However, a traditional method for preparing a black matrix requires the use of organic solvents, which also leads to many problems closely related to environmental protection. In addition, the thicker the black matrix is, the more difficult it is to control the subsequent black matrix patterning process. In addition, the black matrix tends to absorb light, which causes the efficiency to be attenuated and therefore reduced.

### BRIEF SUMMARY

In view of the above problems, the present disclosure provides an optical substrate that is environmentally friendly, can improve the light-emitting efficiency of a display device, and/or can further reduce color interference between pixels of the display device. The present disclosure further provides a display device including the optical substrate, and a method for preparing the display device.

Some embodiments of the present disclosure provide an optical substrate includes a transparent matrix substrate, a reflective film, and a light-absorbing film. The transparent matrix substrate includes a first surface, a second surface opposite the first surface, and a plurality of openings. Each of the openings is in the transparent matrix substrate and includes an opening sidewall connecting the first surface and the second surface. Each of the opening sidewalls includes a first portion and a second portion. The reflective film is attached to the first surface and extends from the first surface to the first portion of the opening sidewall. The light-absorbing film is attached only to the second surface or attached to the second surface and further extending from the second surface to the second portion of the opening sidewall.

Other embodiments of the present disclosure provide a display device. The display device includes an optical substrate, a carrier substrate, and a plurality of light-emitting diodes. The optical substrate includes a transparent matrix substrate, a reflective film, and a light-absorbing film. The transparent matrix substrate includes a first surface, a second surface opposite the first surface, and a plurality of openings. Each of the openings is in the transparent matrix substrate and includes an opening sidewall connecting the first surface and the second surface. Each of the opening sidewalls includes a first portion and a second portion. The reflective film is attached to the first surface and extends from the first surface to the first portion of the opening sidewall. The light-absorbing film is attached only to the second surface or attached to the second surface and further extending from the second surface to the second portion of the opening sidewall. The carrier substrate is disposed under the optical substrate and has a supporting surface. The light-emitting diodes are disposed on the supporting surface of the carrier substrate and are in respective openings of the optical substrate, and a portion of the reflective film is disposed between the supporting surface and the first surface of the optical substrate.

Other embodiments of the present disclosure provide a method for preparing the display device. The method for preparing the display device includes forming an optical substrate, providing a carrier substrate, providing a plurality of light-emitting diodes, and combining the optical substrate with the carrier substrate. The method of forming the optical substrate includes providing a transparent matrix substrate. The transparent matrix substrate includes a first surface, a second surface opposite the first surface, and a plurality of openings in the transparent matrix substrate. Each of the openings includes an opening sidewall connecting the first surface and the second surface. Each of the opening sidewalls includes a first portion and a second portion. The method of forming the optical substrate includes forming a reflective film, wherein the reflective film is attached to the first surface and extends from the first surface to the first portion of the opening sidewall. The method of forming the optical substrate includes forming a light-absorbing film, wherein the light-absorbing film is attached only to the second surface or attached to the second surface and further extending from the second surface to the second portion of the opening sidewall. The carrier substrate includes a supporting surface. The light-emitting diodes are provided on the supporting surface of the carrier substrate. The optical substrate and carrier substrate are bonded so that the light-emitting diodes are disposed in the openings.

### BRIEF DESCRIPTION OF THE DRAWINGS

The following will describe the embodiments of the present disclosure in detail with reference to the accompanying drawings. It should be noted that various features are not drawn to scale and are merely illustrative. In fact, the size of the elements may be enlarged or reduced to clearly present the technical features of the embodiments of the present disclosure.

FIG. 1A is a schematic view of a back side of an optical substrate according to an embodiment of the present disclosure.

FIG. 1B is a schematic view of a front side of an optical substrate according to an embodiment of the present disclosure.

FIG. 2A is a partial cross-sectional schematic view of an optical substrate according to an embodiment of the present disclosure.

FIG. 2B is a partial cross-sectional schematic view of an optical substrate according to another embodiment of the present disclosure.

FIG. 2C is a partial cross-sectional schematic view of an optical substrate according to another embodiment of the present disclosure.

FIG. 3A is a partial cross-sectional schematic view of a display device according to an embodiment of the present disclosure.

FIG. 3B is a partial cross-sectional schematic view of a display device according to another embodiment of the present disclosure.

FIG. 3C is a partial cross-sectional schematic view of a display device according to another embodiment of the present disclosure.

FIGS. 4A to 4G are partial cross-sectional schematic views of a display device and/or a semi-finished product thereof at various stages of a method for preparing the display device according to an embodiment of the present disclosure.

### DETAILED DESCRIPTION OF THE DISCLOSURE

The following provides many different embodiments or examples for implementing various features of the present disclosure. In order to simplify the description, specific examples of various elements and their arrangements are described below. Of course, these specific examples are not intended to be limiting. For example, when the disclosed embodiment describes a first feature being formed on or above a second feature, it means that it may include an embodiment in which the first feature and the second feature are in direct contact, and may also include an embodiment in which an additional feature is formed between the first feature and the second feature so that the first feature and the second feature may not be in direct contact.

It should be understood that additional operating steps may be implemented before, during, or after the method, and in other embodiments of the method, some operating steps may be replaced or omitted.

Further, spatially relative terms, such as “under,” “below,” “lower,” “on,” “above,” “upper” and the like, may be used herein for ease of description to describe one element or feature's relationship to another element(s) or feature(s) as illustrated in the drawings. The spatially relative terms are intended to encompass different orientations of the device in use or operation in addition to the orientation depicted in the drawings. When the device is oriented differently (for example, rotated 90 degrees or at another orientation), spatially relative adjectives used herein should be interpreted based on the oriented orientation.

In the specification, the terms “about”, “approximately” and “substantially” generally mean within 20%, or within 10%, or within 5%, or within 3%, or within 2%, or within 1%, or within 0.5% of a given value or range. Values given here are approximate values, that is, even if there is no specific description of “about”, “approximately”, or “substantially”, the meanings of “about”, “approximately”, or “substantially” may still be implied. In the specification, the expression “a to b” indicates that a range includes values greater than or equal to a and values less than or equal to b.

Unless defined otherwise, all terms (including technical and scientific terms) used herein have the same meaning as commonly understood by one of ordinary skills in the art to which this disclosure belongs. It should be understood that terms, such as those defined in commonly used dictionaries, should be interpreted as having a meaning that conforms to the relative skills of the present disclosure and the background or the context of the present disclosure, and should not be interpreted in an idealized or overly formal manner unless so defined.

The same reference symbols and/or reference signs may be repeated in the different embodiments disclosed below. These repetitions are for convenience and clarity and are not intended to limit any particular relationship between the various embodiments and/or structures discussed.

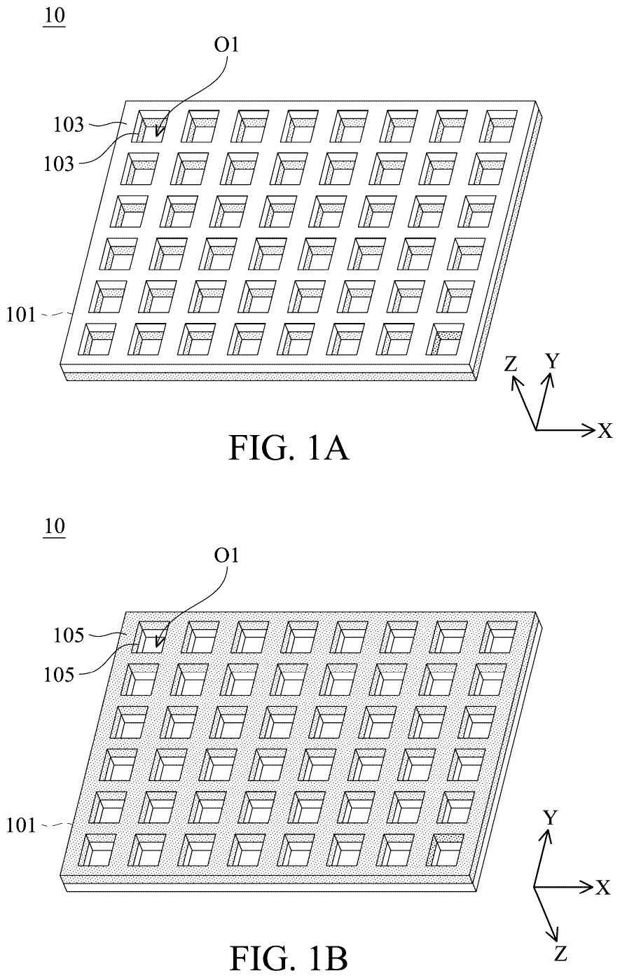

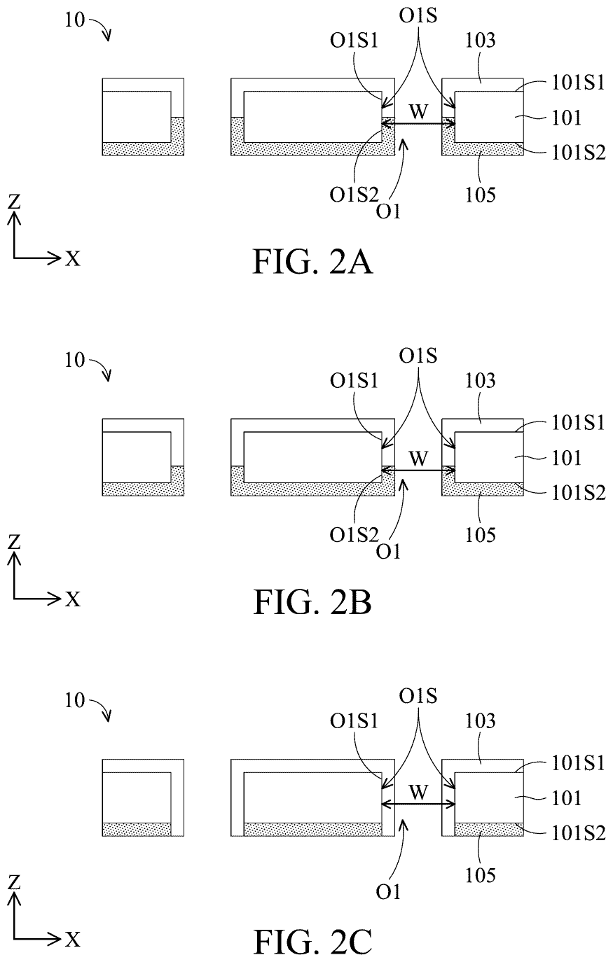

FIG. 1A is a schematic view of a back side of an optical substrate 10 according to an embodiment of the present disclosure. FIG. 1B is a schematic view of a front side of an optical substrate 10 according to an embodiment of the present disclosure. FIG. 2A is a partial cross-sectional schematic view of an optical substrate 10 according to an embodiment of the present disclosure. FIG. 2B is a partial cross-sectional schematic view of an optical substrate 10 according to another embodiment of the present disclosure. FIG. 2C is a partial cross-sectional schematic view of an optical substrate 10 according to another embodiment of the present disclosure. The optical substrate 10 of the present disclosure is further described below with reference to FIGS. 1A to 2C.

One aspect of the present disclosure provides an optical substrate. The optical substrate 10 disclosed in the present disclosure includes a transparent matrix substrate 101, a reflective film 103, and a light-absorbing film 105. As shown in FIG. 1A and FIG. 1B, the reflective film 103 and the light-absorbing film 105 are disposed on opposite surfaces of the transparent matrix substrate 101. Specifically, further referring to FIG. 2A, the transparent matrix substrate 101 includes a first surface 101S1, a second surface 101S2 opposite the first surface 101S1, and a plurality of openings O1. Each of the opening O1 is in the transparent matrix substrate 101 and includes an opening sidewall O1S connecting the first surface 101S1 and the second surface 101S2. Each of the opening sidewalls O1S includes a first portion O1S1 and a second portion O1S2. The reflective film 103 is attached to the first surface 101S1 and extends from the first surface 101S1 to the first portion O1S1 of each opening sidewall O1S. The light-absorbing film 105 is attached to the second surface 101S2 and extends from the second surface 101S2 to the second portion O1S2 of each opening sidewall O1S, as shown in FIG. 2A or FIG. 2B, but the present disclosure is not limited thereto. In some embodiments, a length of the second portion O1S2 is zero, that is, as shown in FIG. 2C, the opening sidewall O1S is only composed of the first portion O1S1. In this embodiment, the reflective film 103 extends from the first surface 101S1 to the first portion O1S1 of each opening sidewall O1S, and the light-absorbing film 105 is only attached to the second surface 101S2.

In some embodiments, the transparent matrix substrate 101 may include a flexible substrate, a rigid substrate, or a combination thereof, but the present disclosure is not limited thereto. In some embodiments, the transparent matrix substrate 101 may include a translucent substrate or a semi-translucent substrate. In some embodiments, materials of the transparent matrix substrate 101 may include glass, quartz, sapphire, ceramic, polyimide (PI), polycarbonate (PC), polyethylene terephthalate (PET), polypropylene (PP), other suitable materials, or any combination thereof, but the present disclosure is not limited thereto. In some embodiments, the transparent matrix substrate 101 may be a glass matrix substrate. In some embodiments, the transparent matrix substrate 101 has a thickness of about 30 μm-500 μm in a normal direction thereof (Z direction).

The transparent matrix substrate 101 includes a plurality of openings O1 penetrating the transparent matrix substrate 101. Each opening O1 has an opening width W and an opening sidewall O1S connecting the first surface 101S1 and the second surface 101S2. That is, in the cross-sectional view, the distance between two opening sidewalls O1S of each opening O1 is the opening width W, as shown in FIG. 2A. The opening widths W of the openings O1 may all be the same, or they may be different from each other. In some embodiments, the opening width W may be 30 μm-500 μm.

The opening sidewall O1S includes a first portion O1S1 and a second portion O1S2. In some embodiments, the ratio of the length of the second portion O1S2 to the length of the first portion O1S1 (the length of the second portion O1S2: the length of the first portion O1S1) is 0:100 to 50:50. the ratio of the length of the second portion O1S2 to the length of the first portion O1S1 being 0:100 means that the opening sidewall O1S may only be composed of the first portion O1S1. FIG. 2A discloses an embodiment in which the ratio of the length of the second portion O1S2 to the length of the first portion O1S1 of the opening sidewall O1S is 1:1 (50:50). FIG. 2B discloses an embodiment in which the ratio of the length of the second portion O1S2 to the length of the first portion O1S1 of the opening sidewall O1S is approximately 1:2. FIG. 2C discloses an embodiment in which the ratio of the length of the second portion O1S2 to the length of the first portion O1S1 of the opening sidewall O1S is 0:100. However, the present disclosure is not limited to these embodiments.

In some embodiments, the reflective film 103 may include a white reflective adhesive film, and the light-absorbing film 105 may include a black light-absorbing adhesive film. In addition, the reflective film 103 may be a single-layer structure or a multi-layer structure including a plurality of layers. In some embodiments, the reflective film 103 has a thickness of about 1 μm to 100 μm in a normal direction thereof (Z direction). In some embodiments, the reflective film 103 may include a first resin and a reflective material. Examples of the first resin may include, but are not limited to, epoxy resins, polystyrenes, polycarbonate resins, polyamides, polyimides, novolac resins, phenolic resins, urea resins, and polyurethanes. Examples of the reflective material may include, but are not limited to, titanium dioxides (TiO₂), silicon oxides (SiOₓ), metal particles, other suitable white pigments, or any combination thereof. In some embodiments, the reflective film 103 may further include other filling particles.

The light-absorbing film 105 may be a single-layer structure or a multi-layer structure including a plurality of layers. In some embodiments, the light-absorbing film 105 has a thickness of about 1 μm to 100 μm in a normal direction thereof (Z direction). In some embodiments, the light-absorbing film 105 may include a second resin and a light-absorbing material. Examples of the second resin may include, but are not limited to, epoxy resins, polystyrenes, polycarbonate resins, polyamides, polyimides, novolac resins, phenolic resins, urea resins, and polyurethanes. Examples of the light-absorbing material may include, but are not limited to, carbon blacks, graphite, metal nitrides, titanium blacks, other suitable black pigments, or any combination thereof. The first resin and the second resin may be the same as or different from each other. In some embodiments, the light-absorbing film 105 may further include other filling particles.

The reflective film 103 of the optical substrate can be used to reflect light, and the light-absorbing film 105 of the optical substrate can be used to increase the contrast of the display device to be applied. Therefore, when the optical substrate including the above structure is applied to a display device, the luminous efficiency of the display device can be improved and/or the color interference between pixels of the display device can be further reduced.

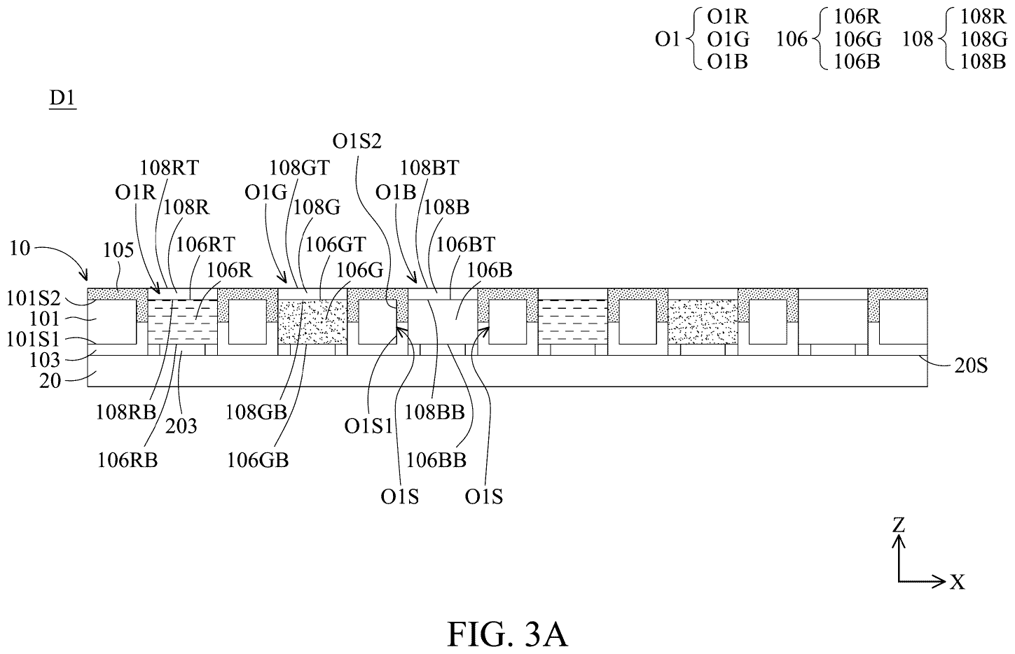

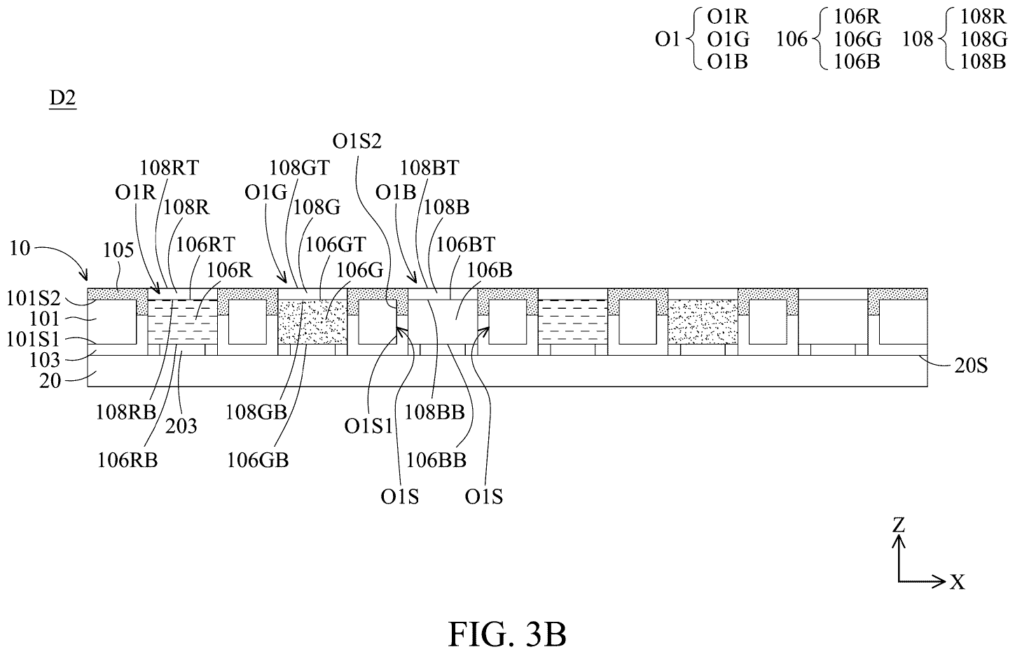

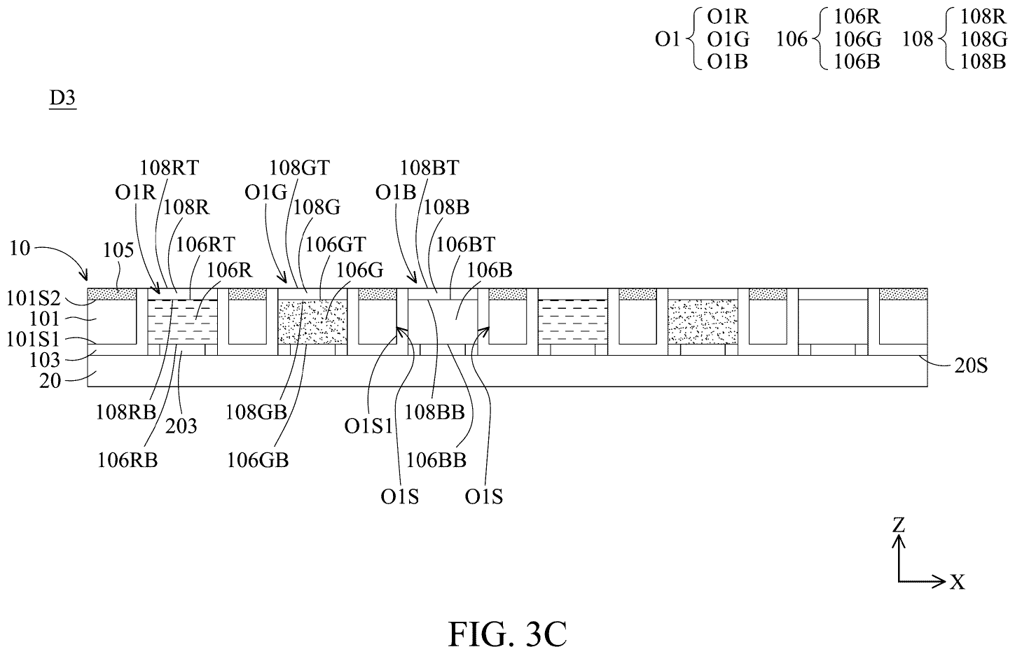

One aspect of the present disclosure provides a display device. FIGS. 3A to 3C are partial cross-sectional schematic views of display devices including the optical substrate of FIGS. 2A to 2C, respectively. As shown in FIGS. 3A to 3C, the display devices D1, D2, and D3 of the present disclosure include the optical substrate 10 above, a carrier substrate 20, and a plurality of light-emitting diodes 203. The carrier substrate 20 includes a supporting surface 20S. The light-emitting diodes 203 are disposed on the supporting surface 20S of the carrier substrate 20 and are located in the respective openings O1 of the optical substrate 10. A portion of the reflective film 103 is between the supporting surface 20S and the first surface 101S1 of the optical substrate 10.

The display device D1 of the present disclosure is further described below with reference to FIG. 3A. As shown in FIG. 3A, in the display device D1, the supporting surface 20S of the carrier substrate 20 faces the first surface 101S1 of the optical substrate 10. Therefore, the portion of the reflective film 103 disposed on the first surface 101S1 of the optical substrate 10 is between the supporting surface 20S and the first surface 101S1 of the optical substrate 10. The light-emitting diode 203 disposed on the supporting surface 20S of the supporting substrate 20 is disposed in the opening 01. In some embodiments, the portion of the reflective film 103 in the opening O1 surrounds the light-emitting diode 203 in the opening O1, as shown in FIG. 3A.

The carrier substrate 20 may be a substrate including conductive circuits for supporting and electrically connecting elements thereon, such as the light-emitting diode 203, a driver IC and other elements. In some embodiments, the carrier substrate 20 may include a flexible substrate, a rigid substrate, or a combination thereof, but the present disclosure is not limited thereto. In some embodiments, the carrier substrate 20 may include a light-translucent substrate or a semi-translucent substrate. In some embodiments, materials of the carrier substrate 20 may include glass, quartz, sapphire, ceramic, polyimide (PI), polycarbonate (PC), polyethylene terephthalate (PET), polypropylene (PP), other suitable materials, or any combination thereof, but the present disclosure is not limited thereto. The carrier substrate 20 may include the same material as or a different material from that of the transparent matrix substrate 101.

In some embodiments, the light-emitting diode 203 may include a blue light-emitting diode to emit blue light, a UV light-emitting diode (UV LED) to emit UV light, or a combination thereof. In addition, the light-emitting diode 203 may be a sub-millimeter light-emitting diode (mini LED) or a micro light-emitting diode (micro LED), but the present disclosure is not limited thereto. In some embodiments, the size of the mini LED ranges from 100 μm to 200 μm. In some embodiments, the size of the micro LED less than 100 μm.

In some embodiments, as shown in FIG. 3A, the display device D1 may further include a plurality of wavelength conversion layers 106 in the openings O1. The light-emitting diodes 203 may be disposed between the wavelength conversion layers 106 and the carrier substrate 20. In some embodiments, the wavelength conversion layers 106 may include a first wavelength conversion layer 106R, a second wavelength conversion layer 106G, and a third wavelength conversion layer 106B. The openings O1 may include a first opening O1R, a second opening O1G, and a third opening O1B. The first wavelength conversion layer 106R, the second wavelength conversion layer 106G, and the third wavelength conversion layer 106B may be disposed in the first opening O1R, the second opening O1G, and the third opening O1B, respectively, as shown in FIG. 3A. Each wavelength conversion layer 106 has an upper surface and a lower surface opposite the upper surface. Specifically, the first wavelength conversion layer 106R has an upper surface 106RT and a lower surface 106RB opposite the upper surface 106RT, the second wavelength conversion layer 106G has an upper surface 106GT and a lower surface 106GB opposite the upper surface 106GT, and the third wavelength conversion layer 106B has an upper surface 106BT and a lower surface 106BB opposite the upper surface 106BT.

In some embodiments, the distance between the upper surface of the wavelength conversion layer 106 and the light-emitting diode 203 is greater than the distance between the lower surface of the wavelength conversion layer 106 and the light-emitting diode 203. Specifically, the distance between the upper surface 106RT of the first wavelength conversion layer 106R and the light-emitting diode 203 is greater than the distance between the lower surface 106RB of the wavelength conversion layer 106 and the light-emitting diode 203. The distance between the upper surface 106GT of the second wavelength conversion layer 106G and the light-emitting diode 203 is greater than the distance between the lower surface 106GB of the second wavelength conversion layer 106G and the light-emitting diode 203. The distance between the upper surface 106BT of the third wavelength conversion layer 106B and the light-emitting diode 203 is greater than the distance between the lower surface 106BB of the third wavelength conversion layer 106B and the light-emitting diode 203.

Furthermore, the portion of the reflective film 103 in each opening O1 may surround the wavelength conversion layer 106 disposed in each opening 01. That is, the first portion O1S1 of the opening sidewall O1S of the opening O1 surrounds the wavelength conversion layer 106, and the reflective film 103 extending and attached to the first portion O1S1 of the opening sidewall O1S of the opening O1 may surround the wavelength conversion layer 106. In more detail, as shown in FIG. 3A, the reflective adhesive films 103 extending and attached to the first portions O1S1 of the opening sidewalls O1S of the first opening O1R, the second opening O1G, and the third opening O1B may surround the first wavelength conversion layer 106R, the second wavelength conversion layer 106G, and the third wavelength conversion layer 106B, respectively.

In some embodiments, the portion of the light-absorbing film 105 in each opening O1 may surround the wavelength conversion layer 106 disposed in each opening O1. That is, the second portion O1S2 of the opening sidewall O1S of the opening O1 surrounds the wavelength conversion layer 106, and the light-absorbing film 105 extending and attached to the second portion O1S2 of the opening sidewall O1S of the opening O1 can surround the wavelength conversion layer 106. As shown in FIG. 3A, the light-absorbing adhesive films 105 extending and attached to the second portions O1S2 of the opening sidewalls O1S of the first opening O1R, the second opening O1G, and the third opening O1B may surround the first wavelength conversion layer 106R, the second wavelength conversion layer 106G, and the third wavelength conversion layer 106B, respectively. In some embodiments, as shown in FIG. 3A, side surfaces of the first wavelength conversion layer 106R, the second wavelength conversion layer 106G, and the third wavelength conversion layer 106B may be surrounded by the reflective adhesive films 103 and the light-absorbing adhesive films 105.

In some embodiments, the first wavelength conversion layer 106R and the second wavelength conversion layer 106G both include phosphors, quantum dot materials or a combination thereof. For example, the first wavelength conversion layer 106R may include red phosphors, red quantum dot materials or a combination thereof, and the second wavelength conversion layer 106G may include green phosphors, green quantum dot materials or a combination thereof, but the present disclosure is not limited thereto. Therefore, in some embodiments, the first wavelength conversion layer 106R absorbs a portion of the light (blue light or ultraviolet light) emitted from the light-emitting diode 203 and converts it to red light, while the second wavelength conversion layer 106G absorbs a portion of the light (blue light or ultraviolet light) emitted from the light-emitting diode 203 and converts it to green light. In some embodiments, the third wavelength conversion layer 106B is a light transmitting layer, the light-emitting diode 203 is a light-emitting diode that emits blue light, and the blue light passes through the light-transmitting layer serving as the third wavelength conversion layer 106B. In some embodiments, the light-transmitting layer may include air, but the present disclosure is not limited thereto. In some embodiments, the third wavelength conversion layer 106B includes phosphors, quantum dot materials or a combination thereof. In some embodiments, the third wavelength conversion layer 106B may include blue phosphors, blue quantum dot materials, or a combination thereof, but the present disclosure is not limited thereto. The third wavelength conversion layer 106B absorbs a portion of the light (ultraviolet light) emitted from the light-emitting diode 203 and converts it into blue light. Therefore, the light-emitting diode 203 disposed in the first opening O1R can emit red light via the first wavelength conversion layer 106R, the light-emitting diode 203 disposed in the second opening O1G can emit green light via the second wavelength conversion layer 106G, and the light-emitting diode 203 disposed in the third opening O1B can emit blue light via the third wavelength conversion layer 106B, but the present disclosure is not limited thereto.

In some embodiments, the display device D1 may further include a plurality of filter layers 108 disposed in the openings O1. The light-emitting diodes 203 may be disposed between the filter layers 108 and the carrier substrate 20. As shown in FIG. 3A, in some embodiments, the filter layers 108 may include a first filter layer 108R, a second filter layer 108G, and a third filter layer 108B, but the disclosure is not limited thereto. Each filter layer 108 has an upper surface and a lower surface opposite the upper surface. Specifically, the first filter layer 108R has an upper surface 108RT and a lower surface 108RB opposite the upper surface 108RT, the second filter layer 108G has an upper surface 108GT and a lower surface 108GB opposite the upper surface 108GT, and the third filter layer 108B has an upper surface 108BT and a lower surface 108BB opposite the upper surface 108BT.

In some embodiments, the distance between the upper surface of the filter layer 108 and the light-emitting diode 203 is greater than the distance between the lower surface of the filter layer 108 and the light-emitting diode 203. Specifically, in some embodiments, the distance between the upper surface 108RT of the first filter layer 108R and the light-emitting diode 203 is greater than the distance between the lower surface 108RB of the first filter layer 108R and the light-emitting diode 203. The distance between the upper surface 108GT of the second filter layer 108G and the light-emitting diode 203 is greater than the distance between the lower surface 108GB of the second filter layer 108G and the light-emitting diode 203. The distance between the upper surface 108BT of the third filter layer 108B and the light-emitting diode 203 is greater than the distance between the lower surface 108BB of the third filter layer 108B and the light-emitting diode 203.

In some embodiments, the lower surface of the filter layer 108 is between the upper surface of the filter layer 108 and the supporting surface 20S of the supporting substrate 20. In some embodiments, the vertical distance between the filter layer 108 and the second surface 101S2 is shorter than the vertical distance between the filter layer 108 and the first surface 101S1. For example, the vertical distance between the lower surface of the filter layer 108 and the second surface 101S2 is shorter than the vertical distance between the lower surface of the filter layer 108 and the first surface 101S1, but the disclosure is not limited thereto. Specifically, in some embodiments, vertical distances between the lower surface 108RB of the first filter layer 108R, the lower surface 108GB of the second filter layer 108G, and the lower surface 108BB of the third filter layer 108B in the first opening O1R, the second opening O1G, and the third opening O1B and the second surface 101S2 of the transparent matrix substrate 101 are all smaller than vertical distances between the lower surface 108RB of the first filter layer 108R, the lower surface 108GB of the second filter layer 108G, and the lower surface 108BB of the third filter layer 108B and the first surface 101S1 of the transparent matrix substrate 101.

In some embodiments, the first filter layer 108R may be a red filter layer that permits red light to pass through, the second filter layer 108G may be a green filter layer that permits green light to pass through, and the third filter layer 108B may be a blue filter layer that permits blue light to pass through, but the present disclosure is not limited thereto. In some embodiments, the third filter layer 108B may be a transparent filter layer that transmits incident light.

In some embodiments, the portion of the light-absorbing film 105 in each opening O1 may surround the filter layer 108 disposed in each opening O1. That is, the second portion O1S2 of the opening sidewall O1S of the opening O1 surrounds the filter layer 108, and the light-absorbing film 105 extending and attached to the second portion O1S2 of the opening sidewall O1S of the opening O1 can surround the filter layer 108. As shown in FIG. 3A, the light-absorbing adhesive films 105 extending and attached to the second portions O1S2 of the opening sidewalls O1S of the first opening O1R, the second opening O1G, and the third opening O1B may surround the first filter layer 108R, the second filter layer 108G, and the third filter layer 108B, respectively, but the present disclosure is not limited thereto.

In some embodiments, the optical substrate 10 may include a plurality of wavelength conversion layers 106 and a plurality of filter layers 108 at the same time. The first filter layer 108R and the first wavelength conversion layer 106R may be disposed in the first opening O1R, the second filter layer 108G and the second wavelength conversion layer 106G may be disposed in the second opening O1G, and the third filter layer 108B and the third wavelength conversion layer 106B may be disposed in the third opening O1B. Each filter layer 108 may be disposed on an upper surface of a corresponding wavelength conversion layer 106. Specifically, in some embodiments, the first filter layer 108R may be disposed on the upper surface 106RT of the first wavelength conversion layer 106R, the second filter layer 108G may be disposed on the upper surface 106GT of the second wavelength conversion layer 106G, and the third filter layer 108B may be disposed on the upper surface 106BT of the third wavelength conversion layer 106B. In this embodiment, the distance between the upper surface 108RT of the first filter layer 108R and the first surface 101S1 of the transparent matrix substrate 101 is greater than the distance between the upper surface 106RT of the first wavelength conversion layer 106R and the first surface 101S1 of the transparent matrix substrate 101. The distance between the upper surface 108GT of the second filter layer 108G and the first surface 101S1 of the transparent matrix substrate 101 is greater than the distance between the upper surface 106GT of the second wavelength conversion layer 106G and the first surface 101S1 of the transparent matrix substrate 101. The distance between the upper surface 108BT of the third filter layer 108B and the first surface 101S1 of the transparent matrix substrate 101 is greater than the distance between the upper surface 106BT of the third wavelength conversion layer 106B and the first surface 101S1 of the transparent matrix substrate 101.

In some embodiments, the upper surface 106RT of the first wavelength conversion layer 106R, the upper surface 106GT of the second wavelength conversion layer 106G, and the upper surface 106BT of the third wavelength conversion layer 106B may respectively contact the lower surface 108RB of the first filter layer 108R, the lower surface 108GB of the second filter layer 108G, and the lower surface 108BB of the third filter layer 108B. In some embodiments, the upper surface 108RT of the first filter layer 108R, the upper surface 108GT of the second filter layer 108G, and the upper surface 108BT of the third filter layer 108B may be flush with the second surface 101S2 of the transparent matrix substrate 101, but the disclosure is not limited thereto. In some embodiments, the upper surface 108RT of the first filter layer 108R, the upper surface 108GT of the second filter layer 108G, and the upper surface 108BT of the third filter layer 108B may be flush with the light-absorbing film 105 on the second surface 101S2 of the transparent matrix substrate 101.

In the embodiment that the optical substrate 10 includes both the wavelength conversion layers 106 and the filter layers 108 in the openings O1, the wavelength conversion layers 106 may be disposed between the filter layers 108 and the light-emitting diodes 203. That is, the light-emitting diode 203, the wavelength conversion layer 106, and the filter layer 108 in the opening O1 may be sequentially stacked on the supporting surface 20S of the carrier substrate 20 along the Z direction, as shown in FIG. 3A, but the present disclosure is not limited thereto.

The display device D2 shown in FIG. 3B includes an optical substrate 10 having the structure as shown in FIG. 2B. The display device D2 is similar to the display device D1, except that the length ratio of the reflective film 103 to the light-absorbing film 105 on the opening sidewall O1S of the optical substrate 10 is different. The other structures are the same and are therefore not described again.

The display device D3 shown in FIG. 3C includes an optical substrate 10 having the structure as shown in FIG. 2C. In this embodiment, the length ratio of the second portion O1S2 to the first portion O1S1 in the opening sidewall O1S of the opening O1 of the optical substrate 10 is 0:100. That is, the opening sidewall O1S is composed only of the first portion O1S1.

In this embodiment, the display device D3 may further include a plurality of filter layers 108 disposed in the openings O1. The portion of the reflective film 103 in each opening O1 may surround the filter layer 108 disposed in each opening 01. That is, the first portion O1S1 of the opening sidewall O1S of the opening O1 surrounds the filter layer 108, and the reflective film 103 extending and attached to the first portion O1S1 of the opening sidewall O1S of the opening O1 may surround the filter layer 108. As shown in FIG. 3C, the reflective film 103 extending and attached to the first portions O1S1 of the opening sidewalls O1S of the first opening O1R, the second opening O1G, and the third opening O1B may surround the first filter layer 108R, the second filter layer 108G, and the third filter layer 108B, respectively, but the present disclosure is not limited thereto.

In addition, the display device D3 is similar to the display device D1, except that the length ratio of the reflective film 103 to the light-absorbing film 105 on the opening sidewall O1S of the optical substrate 10 is different. The other structures are the same and are therefore not described again.

One aspect of the present disclosure provides a method for preparing the display device. The method for preparing the display device includes forming an optical substrate 10, providing a carrier substrate 20, providing a plurality of light-emitting diodes 203, and bonding the optical substrate 10 with the carrier substrate 20. The method of forming the optical substrate 10 includes providing a transparent matrix substrate 101, wherein the transparent matrix substrate 101 includes a first surface 101S1, a second surface 101S2 opposite the first surface 101S1, and a plurality of openings O1 in the transparent matrix substrate 101. Each of the openings O1 includes an opening sidewall O1S connecting the first surface 101S1 and the second surface 101S2. The opening sidewall O1S connecting the first surface 101S1 and the second surface 101S2 includes a first portion O1S1 and a second portion O1S2. The method of forming the optical substrate 10 includes forming a reflective film 103 and forming a light-absorbing film 105. In the step of forming the reflective film 103, the reflective film 103 is attached to the first surface 101S1 and extends from the first surface 101S1 to the first portion O1S1 of each opening sidewall O1S. In the step of forming the light-absorbing film 105, the light-absorbing film 105 is attached only to the second surface 101S2 or attached to the second surface 101S2 and further extends from the second surface 101S2 to the second portion O1S2 of each opening sidewall O1S. The carrier substrate 20 includes a supporting surface 20S. In the step of providing the plurality of light-emitting diodes 203, the light-emitting diodes 203 are provided on the supporting surface 20S of the carrier substrate 20. The optical substrate 10 and carrier substrate 20 are bonded so that the light-emitting diodes 203 are disposed in the openings O1.

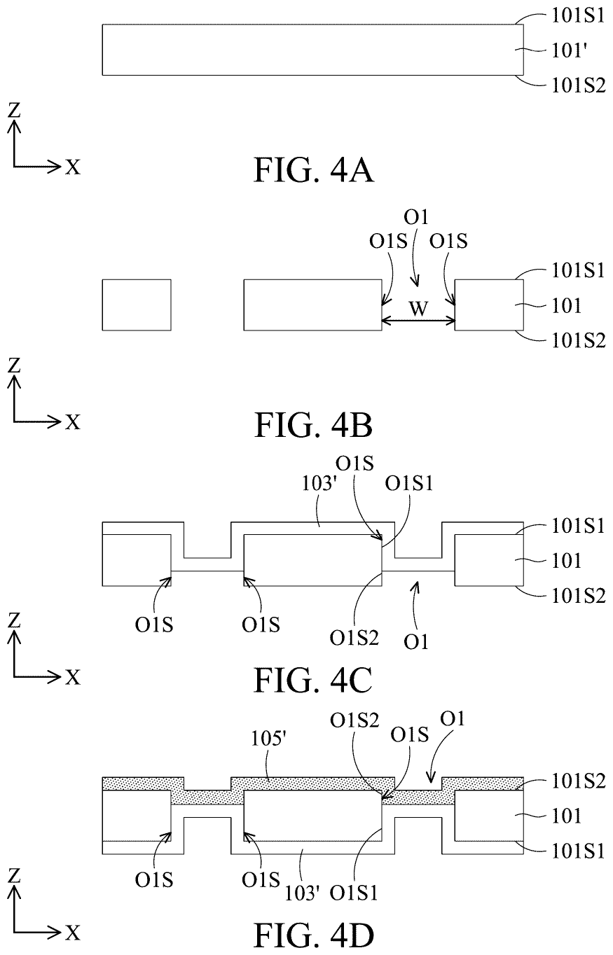

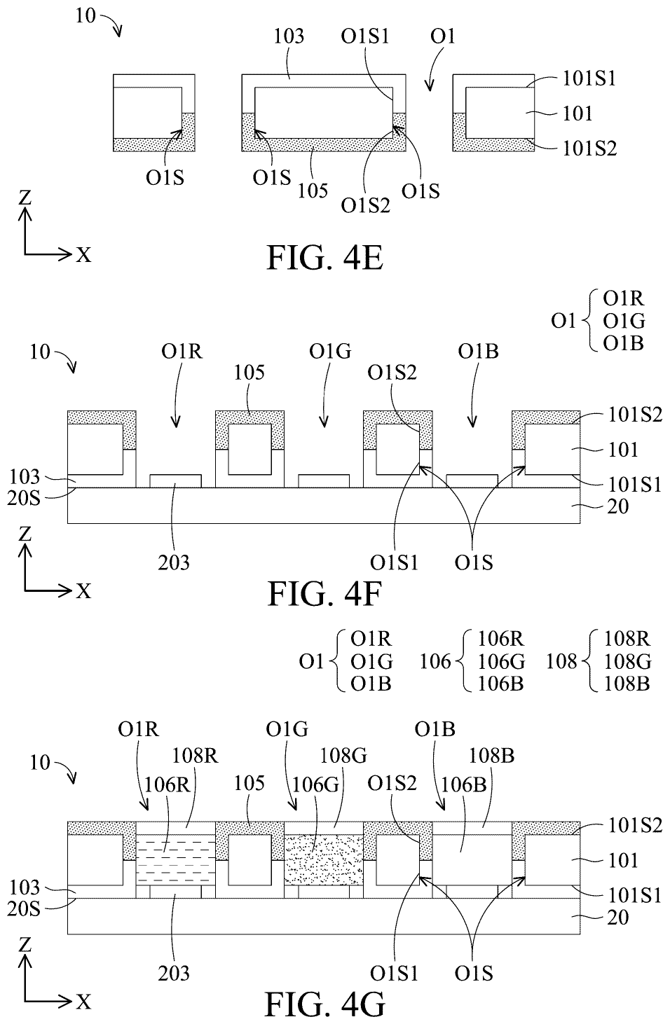

FIGS. 4A to 4G are partial cross-sectional schematic views of a display device and/or a semi-finished product thereof at various stages of a method for preparing the display device according to an embodiment of the present disclosure. The following further describes the method for preparing the display device disclosed in the present disclosure in detail with reference to FIGS. 4A to 4G.

In the method for preparing the display device disclosed herein, the step of forming the optical substrate 10 may be performed before, after, or simultaneously with the step of providing the carrier substrate 20. The method of forming the optical substrate 10 includes providing a transparent matrix substrate 101. The method of providing the transparent matrix substrate 101 includes providing a transparent substrate 101′ including a first surface 101S1 and a second surface 101S2 opposite the first surface 101S1, as shown in FIG. 4A; and performing an etching process on the transparent substrate 101′ to form a plurality of openings O1 passing through the transparent substrate 101′, thereby obtaining the transparent matrix substrate 101, as shown in FIG. 4B. Each opening O1 has an opening sidewall O1S connecting the first surface 101S1 and the second surface 101S2. Each opening sidewall O1S includes a first portion O1S1 and a second portion O1S2, wherein the length ratio of the second portion O1S2 to the first portion O1S1 is 0:100 to 50:50. The etching process may include a dry etching process, a wet etching process, or a combination thereof. Examples of the dry etching process may include a laser etching process, a reactive ion etching process, and an atomic layer etching process, but the present disclosure is not limited thereto.

The step of forming the reflective film 103 may be performed before, after, or simultaneously with the step of forming the light-absorbing film 105. The following provides an embodiment of simultaneously performing the step of forming the reflective film 103 and the step of forming the light-absorbing film 105 as an example, and illustrates the steps of forming the optical substrate 10 with reference to FIGS. 4C to 4E.

In some embodiments, the step of forming the reflective film 103 may include continuously attaching a semi-solid reflective film 103′ along the first surface 101S1 of the transparent matrix substrate 101 to the first portion O1S1 of the opening sidewall O1S of the opening O1. At this time, the semi-solid reflective film 103′ covers the entire opening O1 and the first surface 101S1 of the transparent matrix substrate 101. That is, in the cross-sectional view, the semi-solid reflective adhesive films 103′ attached to the two opening sidewalls O1S of each opening O1 are connected to each other, as shown in FIG. 4C.

In some embodiments, the semi-solid reflective film 103′ may be a white semi-solid (B-stage) adhesive film. In some embodiments, the semi-solid reflective film 103′ may include a reflective material and a semi-solid (B-stage) adhesive material. The “semi-solid (B-stage) adhesive material” in the present disclosure refers to a two-stage thermosetting adhesive material that needs to be baked twice to be fully cured. In some embodiments, the semi-solid adhesive material is a semi-cured material formed by a reaction between a resin and a curing agent. The semi-solid adhesive can be fully cured by further heating. The semi-solid adhesive material may include a thermosetting resin, but the present disclosure is not limited thereto. Examples of the reflective material may include, but are not limited to, titanium dioxides (TiO₂), silicon oxides (SiOₓ), metal particles, other suitable white pigments, or any combination thereof, but the present disclosure is not limited thereto.

In some embodiments, the step of forming the light-absorbing film 105 may include attaching a semi-solid light-absorbing film 105′ to the second surface 101S2 of the transparent matrix substrate 101 or continuously attaching the semi-solid light-absorbing film 105′ along the second surface 101S2 of the transparent matrix substrate 101 to the second portion O1S2 of the opening sidewall O1S of the opening O1, as shown in FIG. 4D. In some embodiments, the step of attaching the semi-solid light-absorbing film 105′ may be performed after the semi-solid reflective film 103′ is attached, but the present disclosure is not limited thereto. At this time, the semi-solid light-absorbing film 105′ covers the entire opening O1 and the second surface 101S2 of the transparent matrix substrate 101. The semi-solid light-absorbing film 105′ covering the opening O1 may be connected to the semi-solid reflective film 103′ covering the opening O1 in the opening O1 or outside the opening O1. In some embodiments, the step of attaching the semi-solid light-absorbing film 105′ may be performed before attaching the semi-solid reflective film 103′.

In some embodiments, the semi-solid light-absorbing film 105′ may be a black semi-solid adhesive film. In some embodiments, the semi-solid light-absorbing film 105′ may include a light-absorbing material and a semi-solid adhesive material. The semi-solid adhesive material may include a thermosetting resin, but the present disclosure is not limited thereto. Examples of the light-absorbing material may include, but are not limited to, carbon blacks, graphite, metal nitrides, titanium blacks, other suitable black pigments, or any combination thereof, but the present disclosure is not limited thereto. The semi-solid adhesive material in the semi-solid light-absorbing film 105′ may be the same as or different from the semi-solid adhesive material in the semi-solid reflective film 103′.

In some embodiments, the step of forming the reflective film 103 and the light-absorbing film 105 further includes, after the step of attaching the semi-solid reflective film 103′ and the semi-solid light-absorbing film 105′, curing the semi-solid light-absorbing film 105′ and the semi-solid reflective film 103′ to form a cured reflective film 103 and a cured light-absorbing film 105, and then removing the reflective film 103 and the light-absorbing film 105 that are not attached to the opening sidewall O1S in the opening O1 and leaving the reflective film 103 and the light-absorbing film 105 attached to the opening sidewall O1S, as shown in FIG. 4E, but the present disclosure is not limited thereto. The step of curing the semi-solid light-absorbing film 105′ and the semi-solid reflective film 103′ may include baking the semi-solid light-absorbing film 105′ and the semi-solid reflective film 103′, but the present disclosure is not limited thereto. In addition, the step of removing the reflective film 103 and the light-absorbing film 105 that are not attached to the opening sidewall O1S in the opening O1 may include a dry etching process, a wet etching process, or a combination thereof. Examples of the dry etching process may include a laser etching process, a reactive ion etching process, and an atomic layer etching process, but the present disclosure is not limited thereto.

In other embodiments, the step of forming the reflective film 103 and the light-absorbing film 105 further includes removing the semi-solid light-absorbing film 105′ and the semi-solid reflective film 103′ that are not attached to the opening sidewall O1S in the opening O1 after the step of attaching the semi-solid reflective film 103′ and the semi-solid light-absorbing film 105′, and then curing the semi-solid light-absorbing film 105′ and the semi-solid reflective film 103′ that are still attached to the opening sidewall O1S to form a cured reflective film 103 and a cured light-absorbing film 105, as shown in FIG. 4E. The step of curing the semi-solid light-absorbing film 105′ and the semi-solid reflective film 103′ may include baking the semi-solid light-absorbing film 105′ and the semi-solid reflective film 103′, but the present disclosure is not limited thereto. The step of removing the semi-solid light-absorbing film 105′ and the semi-solid reflective film 103′ in the opening O1 that are not attached to the opening sidewall O1S may include a dry etching process, a wet etching process, or a combination thereof. Examples of the dry etching process may include a laser etching process, a reactive ion etching process, and an atomic layer etching process, but the present disclosure is not limited thereto.

The step of forming the optical substrate 10 is completed after forming the reflective film 103 and the light-absorbing film 105.

The carrier substrate 20 including the supporting surface 20S can be provided after a cleaning process. The light-emitting diodes 203 can be disposed on the supporting surface 20S of the carrier substrate 20 in any conventional manner.

After providing the light-emitting diodes 203, the optical substrate 10 and the carrier substrate 20 are bonded in such a manner that the first surface 101S1 of the optical substrate 10 faces the supporting surface 20S of the carrier substrate 20 on which the light-emitting diodes 203 are disposed, as shown in FIG. 4F. In some embodiments, the optical substrate 10 and the carrier substrate 20 may be bonded together by a thermal pressing process, but the present disclosure is not limited thereto.

In some embodiments, the method of preparing the optical substrate disclosed herein may further include steps of forming a plurality of wavelength conversion layers and/or forming a plurality of filter layers in the respective openings. In some embodiments, the wavelength conversion layers 106 may be formed by a dispensing process, but the present disclosure is not limited thereto. The filter layers 108 may be formed by an exposure process, a development process, and an etching process, but the present disclosure is not limited thereto. The steps of forming the wavelength conversion layers 106 and/or the filter layers 108 may be performed before or after the optical substrate 10 and the carrier substrate 20 are bonded. The following provides an embodiment in which the steps of forming the wavelength conversion layers 106 and the filter layers 108 are performed after the optical substrate 10 and the carrier substrate 20 are bonded as an example, and the method for preparing the display device disclosed in the present disclosure is described in conjunction with FIG. 4G.

In the embodiment shown in FIG. 4G, after the optical substrate 10 and the carrier substrate 20 are bonded, a wavelength conversion layer 106 is formed on the light-emitting diode 203 in the opening O1, and then a filter layer 108 is formed on the corresponding wavelength conversion layer 106 in the opening O1. The corresponding wavelength conversion layer 106 is disposed between the filter layer 108 and the light-emitting diode 203. In some embodiments, the portion of the reflective film 103 in the opening O1 may surround the wavelength conversion layer 106 and the light-emitting diode 203. Specifically, referring to FIG. 4G, in some embodiments, the wavelength conversion layers 106 may include a first wavelength conversion layer 106R, a second wavelength conversion layer 106G, and a third wavelength conversion layer 106B. The filter layers 108 may include a first filter layer 108R, a second filter layer 108G, and a third filter layer 108B. The first wavelength conversion layer 106R may be formed on the light-emitting diode 203 in the first opening O1R, and the first filter layer 108R may be formed on the first wavelength conversion layer 106R, such that the first wavelength conversion layer 106R is disposed between the light-emitting diode 203 and the first filter layer 108R. In some embodiments, the portion of the reflective film 103 in the first opening O1R may surround the first wavelength conversion layer 106R and the light-emitting diode 203, and the portion of the light-absorbing film 105 in the first opening O1R may surround the first filter layer 108R, but the disclosure is not limited thereto. In some embodiments, the portion of the reflective film 103 in the first opening O1R may surround the first wavelength conversion layer 106R, the first filter layer 108R, and the light-emitting diode 203. The second wavelength conversion layer 106G may be formed on the light-emitting diode 203 in the second opening O1G, and the second filter layer 108G may be formed on the second wavelength conversion layer 106G, such that the second wavelength conversion layer 106G is disposed between the light-emitting diode 203 and the second filter layer 108G. In some embodiments, the portion of the reflective film 103 in the second opening O1G may surround the second wavelength conversion layer 106G and the light-emitting diode 203, and the portion of the light-absorbing film 105 in the second opening O1G may surround the second filter layer 108G, but the disclosure is not limited thereto. In some embodiments, the portion of the reflective film 103 in the second opening O1G may surround the second wavelength conversion layer 106G, the second filter layer 108G, and the light-emitting diode 203. The third wavelength conversion layer 106B may be formed on the light-emitting diode 203 in the third opening O1B, and the third filter layer 108B may be formed on the third wavelength conversion layer 106B, such that the third wavelength conversion layer 106B is disposed between the light-emitting diode 203 and the third filter layer 108B. In some embodiments, the portion of the reflective film 103 in the third opening O1B may surround the third wavelength conversion layer 106B and the light-emitting diode 203, and the portion of the light-absorbing film 105 in the third opening O1B may surround the third filter layer 108B, as shown in FIG. 3B and FIG. 3A, but the present disclosure is not limited thereto. In some embodiments, the portion of the reflective film 103 in the third opening O1B may surround the third wavelength conversion layer 106B, the third filter layer 108B, and the light-emitting diode 203, as shown in FIG. 3C.

The method for preparing the optical substrate disclosed herein uses a reflective film and a light-absorbing film, which can reduce the amount of organic solvent used and is more environmentally friendly. The method for preparing the display device disclosed in the present disclosure may be completed after combining the optical substrate 10 and the carrier substrate 20, after forming the wavelength conversion layer 106, and/or after forming the filter layer 108. In some embodiments, the display device prepared by the method for preparing the display device disclosed herein may have a structure as shown in FIG. 4G, but the disclosure is not limited thereto. The display device prepared by the method for preparing the display device disclosed in the present disclosure may have improved luminous efficiency and/or further reduced color interference between pixels.

Although embodiments of the present disclosure and the advantages thereof have been disclosed as described above, it should be understood that changes, substitutions and modifications may be made without departing from the spirit and scope of the disclosure. In addition, the protection scope of the present disclosure is not limited to the processes, machines, fabrications, compositions, devices, methods and steps in the specific embodiments described in the specification. According to the embodiments of the present disclosure, a person of ordinary skill in the art may understand that current or future processes, machines, fabrications, compositions, devices, methods and steps capable of performing substantially the same functions or achieving substantially the same results may be used in the embodiments of the present disclosure. Therefore, the protection scope of the present disclosure includes the above-mentioned processes, machines, fabrications, compositions, devices, methods and steps. In addition, features of different embodiments may be used together arbitrary as long as they do not violate the spirit of the disclosure or conflict with each other. Each claim constitutes an individual embodiment, and the protection scope of the present disclosure includes the combination of the claims and embodiments.

What is claimed is:

1. An optical substrate, comprising:
a transparent matrix substrate, comprising:
a first surface;
a second surface opposite the first surface; and
a plurality of openings disposed in the transparent matrix substrate, each of the plurality of openings comprising an opening sidewall connecting the first surface and the second surface, wherein the opening sidewall comprises a first portion and a second portion;
a reflective film attached to the first surface and extending from the first surface to the first portion of the opening sidewall; and
a light-absorbing film attached only to the second surface or attached to the second surface and further extending from the second surface to the second portion of each opening sidewall.

2. The optical substrate as claimed in claim 1, wherein the transparent matrix substrate is a glass matrix substrate.

3. The optical substrate as claimed in claim 1, wherein the reflective film comprises a white reflective film, and the light-absorbing film comprises a black light-absorbing film.

4. The optical substrate as claimed in claim 1, wherein a ratio of a length of the second portion to a length of the first portion of each opening sidewall is 0:100 to 50:50.

5. A display device, comprising:
an optical substrate, comprising:
a transparent matrix substrate, comprising:
a first surface;
a second surface opposite the first surface; and
a plurality of openings disposed in the transparent matrix substrate, each of the plurality of openings comprising an opening sidewall connecting the first surface and the second surface, wherein the opening sidewall comprises a first portion and a second portion;
a reflective film attached to the first surface and extending from the first surface to the first portion of the opening sidewall; and
a light-absorbing film attached only to the second surface or attached to the second surface and further extending from the second surface to the second portion of each opening sidewall;
a carrier substrate disposed under the optical substrate and having a supporting surface; and
a plurality of light-emitting diodes disposed on the supporting surface of the carrier substrate and located in the respective openings of the optical substrate, and a portion of the reflective film is disposed between the supporting surface and the first surface of the optical substrate.

6. The display device as claimed in claim 5, wherein the transparent matrix substrate is a glass matrix substrate.

7. The display device as claimed in claim 5, wherein the reflective film comprises a white reflective film, and the light-absorbing film comprises a black light-absorbing film.

8. The display device as claimed in claim 5, wherein a ratio of a length of the second portion to a length of the first portion is 0:100 to 50:50.

9. The display device as claimed in claim 5, further comprising a plurality of wavelength conversion layers, wherein the plurality of wavelength conversion layers are respectively disposed on the light-emitting diodes in the openings, and the portion of the reflective film in each opening surrounds the corresponding wavelength conversion layer and the light-emitting diode.

10. The display device as claimed in claim 9, further comprising a plurality of filter layers, wherein the plurality of filter layers are respectively disposed on the corresponding wavelength conversion layers in the openings, and a distance between each filter layer and the second surface is shorter than a distance between each filter layer and the first surface in the openings.

11. The display device as claimed in claim 5, wherein the light-emitting diodes emit blue light or UV light.

12. A method for preparing a display device, comprising:
forming an optical substrate, wherein the method of forming the optical substrate comprises:
providing a transparent matrix substrate comprising a first surface, a second surface opposite the first surface, and a plurality of openings in the transparent matrix substrate, wherein each of the openings comprises an opening sidewall connecting the first surface and the second surface, and the opening sidewalls comprise a first portion and a second portion;
forming a reflective film, wherein the reflective film is attached to the first surface and extends from the first surface to the first portion of each opening sidewall; and
forming a light-absorbing film, wherein the light-absorbing film is attached only to the second surface or attached to the second surface and further extends from the second surface to the second portion of each opening sidewall;
providing a carrier substrate comprising a supporting surface;
providing a plurality of light-emitting diodes on the supporting surface of the carrier substrate; and
bonding the optical substrate with the carrier substrate so that the light-emitting diodes are disposed in the openings.

13. The method for preparing the display device as claimed in claim 12, wherein the step of forming the reflective film and the light-absorbing film comprises:
forming a semi-solid reflective film, which is continuously attached along the first surface of the transparent matrix substrate to the first portion of each opening sidewall; and
forming a semi-solid light-absorbing film, which is attached to the second surface of the transparent matrix substrate or continuously attached along the second surface of the transparent matrix substrate to the second portion of each opening sidewall.

14. The method for preparing the display device as claimed in claim 13, wherein the step of forming the reflective film and the light-absorbing film further comprises:
curing the semi-solid reflective film and the semi-solid light-absorbing film to form a cured reflective film and a cured light-absorbing film; and
removing the cured reflective film and the cured light-absorbing film that are not attached to the opening sidewall in each opening and leaving the cured reflective film and the cured light-absorbing film attached to each opening sidewall.

15. The method for preparing the display device as claimed in claim 13, wherein the step of forming the reflective film and the light-absorbing film further comprises:
removing the semi-solid reflective film and the semi-solid light-absorbing film that are not attached to the opening sidewall in each opening; and
curing the semi-solid reflective film and the semi-solid light-absorbing film that are attached to the opening sidewall to form a cured reflective film and a cured light-absorbing film.

16. The method for preparing the display device as claimed in claim 12, further comprising:
forming a plurality of wavelength conversion layers on the light-emitting diodes in the respective openings, wherein the portion of the reflective film in each opening surrounds the corresponding wavelength conversion layer and the corresponding light-emitting diode; and
forming a plurality of filter layers on the wavelength conversion layers in the openings, wherein in each opening, the wavelength conversion layer is between the corresponding filter layer and the corresponding light-emitting diode.

17. The method for preparing the display device as claimed in claim 12, wherein the ratio of a length of the second portion to a length of the first portion is 0:100 to 50:50.

18. The method for preparing the display device as claimed in claim 12, wherein the reflective film comprises a white reflective film, and the light-absorbing film comprises a black light-absorbing film.
